(19) United States
(12) Patent Application Publication
(10) Pub. No.: US 2024/0271323 A1
(43) Pub. Date: Aug. 15, 2024

(54) DEVICE AND METHOD FOR PRODUCING GROUP III NITRIDE CRYSTAL

(71) Applicant: Panasonic Holdings Corporation, Osaka (JP)

(72) Inventors: JUNICHI TAKINO, Osaka (JP); MASAYUKI HOTEIDA, Osaka (JP); SHUNICHI MATSUNO, Kyoto (JP)

(21) Appl. No.: 18/633,576

(22) Filed: Apr. 12, 2024

Related U.S. Application Data
(63) Continuation of application No. PCT/JP2022/035068, filed on Sep. 21, 2022.

(30) Foreign Application Priority Data
Oct. 27, 2021 (JP) 2021-175780

(51) Int. Cl. C30B 29/40; C30B 25/12

(52) U.S. Cl. CPC C30B 29/403; C30B 25/12

(57) ABSTRACT

A device for producing a group III nitride crystal includes a raw material chamber that generates a group III element oxide gas, and a growth chamber that causes the group III element oxide gas supplied from the raw material chamber to react with a nitrogen element-containing gas to generate a group III nitride crystal on a seed substrate, wherein the growth chamber includes, on a back surface side of the seed substrate, a structure of promoting heat release from the back surface side of the seed substrate, the structure including a substrate tray on which the seed substrate is placed, a substrate susceptor on which the substrate tray is placed, and a rotary shaft on which the substrate susceptor is placed.

### TECHNICAL FIELD

The present disclosure relates to a device and a method for producing a group III nitride crystal.

### BACKGROUND ART

The group III nitride crystal such as GaN is expected to be applied to next-generation optical devices such as a high-output LED (light emitting diode) and an LD (laser diode), and next-generation electronic devices such as a high-output power transistor mounted on an EV (electric vehicle), a PHV (plug-in hybrid vehicle), and the like. As a method for producing a group III nitride crystal, an oxide vapor phase epitaxy (OVPE) method using a group III oxide as a raw material is used (see, for example, PTL 1).

An example of the reaction system in the OVPE method is as follows.
(1) Ga is heated, and in this state, H₂O gas is introduced. The introduced H₂O gas reacts with Ga to generate Ga₂O gas (Formula (I)).
(2) Then, an NH₃ gas is introduced, and the NH₃ gas is caused to react with the generated Ga₂O gas to generate a GaN crystal on a seed substrate (Formula (II)).

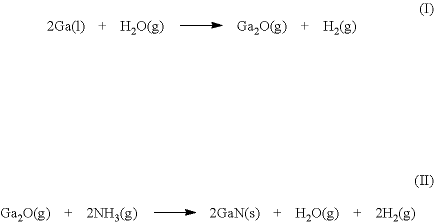

### CITATION LIST

### Patent Literature

PTL 1: WO 2015/053341 A

### SUMMARY OF THE INVENTION

A device for producing a group III nitride crystal according to an aspect of the present disclosure includes a raw material chamber that generates a group III element oxide gas, and a growth chamber that causes the group III element oxide gas supplied from the raw material chamber to react with a nitrogen element-containing gas to generate a group III nitride crystal on a seed substrate, wherein the growth chamber includes, on a back surface side of the seed substrate, a structure of promoting heat release from the back surface side of the seed substrate, the structure including a substrate tray on which the seed substrate is placed, a substrate susceptor on which the substrate tray is placed, and a rotary shaft on which the substrate susceptor is placed.

A method for producing a group III nitride crystal according to an aspect of the present disclosure includes reacting a group III element source with a reactive gas to generate a group III element oxide gas, reacting the group III element oxide gas with a nitrogen element-containing gas to generate a group III nitride crystal on a seed substrate, and providing, on the seed substrate, a temperature gradient in which a difference between a front surface temperature of the seed substrate and a back surface temperature of the seed substrate obtained by subtracting the back surface temperature from the front surface temperature is 0 or a positive numerical value.

### BRIEF DESCRIPTION OF THE DRAWINGS

FIG. 1 is a schematic sectional view illustrating a sectional configuration of a device for producing a group III nitride crystal according to a first exemplary embodiment.

FIG. 2 is a flowchart illustrating a method for producing a group III nitride crystal according to the first exemplary embodiment.

FIG. 3A is a schematic sectional view illustrating an example of shapes of a substrate tray, a substrate susceptor, and a rotary shaft when the substrate tray and the substrate susceptor are in contact with each other on the entire surface, and the substrate susceptor and the rotary shaft are in contact with each other on the entire surface.

FIG. 3B is a schematic sectional view illustrating an example of shapes of a substrate tray, a substrate susceptor, and a rotary shaft when the substrate tray and the substrate susceptor are partially in contact with each other, and the substrate susceptor and the rotary shaft are partially in contact with each other.

FIG. 4A is a graph illustrating a relationship between the ratio of a contact area to a surface area and the number of generated polycrystals.

FIG. 4B is a graph illustrating a relationship between the ratio of a contact area to a surface area and the temperature gradient in a crystal.

### DESCRIPTION OF EMBODIMENT

In the production method described in PTL 1, it may difficult to control the temperature gradient upstream of the substrate and the temperature gradient inside the substrate, and it is difficult to realize stable single crystal growth. Specifically, when the crystallization reaction is an exothermic reaction, and the temperature gradient [(front surface temperature)−(back surface temperature)] from the front surface to the back surface of the crystal is negative, polycrystals are generated due to the Mullins-Sekerka instability, and deterioration of crystal quality is likely to occur.

The present disclosure has been made to solve the above problems, and an object of the present disclosure is to provide a device and a method for producing a group III nitride crystal capable of suppressing the generation of polycrystals and producing a high-quality group III nitride crystal.

A device for producing a group III nitride crystal according to a first aspect includes a raw material chamber that generates a group III element oxide gas, and a growth chamber that causes the group III element oxide gas supplied from the raw material chamber to react with a nitrogen element-containing gas to generate a group III nitride crystal on a seed substrate, wherein the growth chamber includes, on a back surface side of the seed substrate, a structure of promoting heat release from the back surface side of the seed substrate, the structure including a substrate tray on which the seed substrate is placed, a substrate susceptor on which the substrate tray is placed, and a rotary shaft on which the substrate susceptor is placed.

A device for producing a group III nitride crystal according to a second aspect is the device for producing a group III nitride crystal according to the first aspect, wherein the substrate tray and the substrate susceptor may be in contact with each other over an entire surface of the substrate susceptor.

A device for producing a group III nitride crystal according to a third aspect is the device for producing a group III nitride crystal according to the first aspect, wherein the substrate tray and the substrate susceptor may include a contact part where the substrate tray and the substrate susceptor are in contact with each other at a part of a surface of the substrate susceptor and a non-contact part where the substrate tray and the substrate susceptor are not in contact with each other.

A device for producing a group III nitride crystal according to a fourth aspect is the device for producing a group III nitride crystal according to the third aspect, wherein the non-contact part between the substrate tray and the substrate susceptor may overlap a region where the rotary shaft is disposed in a plan view as viewed from a direction of the rotary shaft.

A device for producing a group III nitride crystal according to a fifth aspect is the device for producing a group III nitride crystal according to the third or fourth aspect, wherein the non-contact part may be larger than a region where the rotary shaft is disposed.

A device for producing a group III nitride crystal according to a sixth aspect is the device for producing a group III nitride crystal according to any one of the third to fifth aspects, wherein a ratio between a surface area of the substrate tray and a contact area may be more than or equal to 0.34, the contact area being an area where the substrate tray and the substrate susceptor are in contact with each other.

A device for producing a group III nitride crystal according to a seventh aspect is the device for producing a group III nitride crystal according to any one of the first to sixth aspects, wherein the rotary shaft may include a structure that circulates cooling water inside the rotary shaft.

A device for producing a group III nitride crystal according to an eighth aspect is the device for producing a group III nitride crystal according to any one of the first to seventh aspects, wherein the substrate tray may be made of a material including at least one selected from the group consisting of SiC, C, BN, SiO₂, SiN, AlN, and a transition metal.

A device for producing a group III nitride crystal according to a ninth aspect is the device for producing a group III nitride crystal according to any one of the first to eighth aspects, wherein the substrate susceptor may be made of a material including at least one selected from the group consisting of SiC, C, BN, SiO₂, SiN, AlN, and a transition metal.

A method for producing a group III nitride crystal according to a tenth aspect includes reacting a group III element source with a reactive gas to generate a group III element oxide gas, reacting the group III element oxide gas with a nitrogen element-containing gas to generate a group III nitride crystal on a seed substrate, and providing, on the seed substrate, a temperature gradient in which a difference between a front surface temperature of the seed substrate and a back surface temperature of the seed substrate obtained by subtracting the back surface temperature from the front surface temperature is 0 or a positive numerical value.

The device and method for producing a group III nitride crystal according to the present disclosure can reduce polycrystals and can produce a high-quality group III nitride crystal.

Hereinafter, a device and a method for producing a group III nitride crystal according to exemplary embodiments will be described with reference to the drawings. In the following description, the same components are denoted by the same reference marks, and the description thereof is appropriately omitted.

### First Exemplary Embodiment

### <Outline of Device for Producing Group III Nitride Crystal>

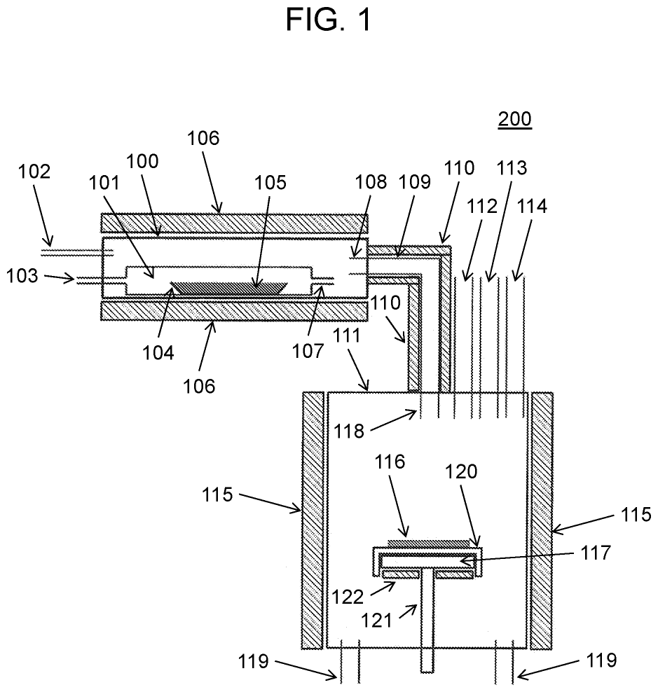

An outline of device 200 for producing a group III nitride crystal according to a first exemplary embodiment of the present disclosure will be described with reference to a schematic view of FIG. 1. FIG. 1 is a schematic sectional view illustrating a sectional configuration of device 200 for producing a group III nitride crystal according to the first exemplary embodiment. FIG. 1 is a schematic view, and the size, ratio, and the like of each component may be different from the actual size, ratio, and the like.

Device 200 for producing a group III nitride crystal according to the first exemplary embodiment includes raw material chamber 100 that generates a group III element oxide gas, and growth chamber 111 that generates a group III nitride crystal on a seed substrate. Raw material reaction room 101 is disposed in raw material chamber 100, and raw material boat 104 on which starting group III element source 105 is placed is disposed in raw material reaction room 101. In the present exemplary embodiment, starting group III element source 105 is a starting Ga source. Raw material reaction room 101 is connected with reactive gas supply pipe 103 that supplies a reactive gas that reacts with starting group III element source 105. Raw material reaction room 101 includes group III element oxide gas discharge port 107. When starting group III element source 105 is an oxide, a reducing gas is used as the reactive gas. When starting group III element source 105 is a metal, an oxidizing gas is used as the reactive gas. Raw material chamber 100 is provided with first carrier gas supply port 102. A first carrier gas supplied from first carrier gas supply port 102 carries the group III element oxide gas discharged from group III element oxide gas discharge port 107, from gas discharge port 108 through connection pipe 109 to growth chamber 111.

Growth chamber 111 includes gas supply port 118 that supplies the group III element oxide gas and the first carrier gas, third carrier gas supply port 112, nitrogen element-containing gas supply port 113, second carrier gas supply port 114, and discharge port 119. Substrate tray 120 on which seed substrate 116 is placed is disposed in growth chamber 111. Substrate tray 120 is placed on substrate susceptor 117. Substrate susceptor 117 is placed on rotary shaft 121. Growth chamber 111 includes fourth heater 122 below substrate susceptor 117.

The device for producing a group III nitride crystal according to the first embodiment of the present disclosure has a structure (heat release promoting structure) in which heat release from the back surface side of the seed substrate is promoted by substrate tray 120, substrate susceptor 117, and rotary shaft 121 in the growth chamber, and thus the temperature gradient [(front surface temperature)−(back surface temperature)] from the front surface to the back surface of seed substrate 116 becomes 0 or a positive numerical value. This structure forms a heat flow from the substrate tray to the rotation shaft and causes heat release from the front surface to the back surface of the seed substrate. Having the heat release promoting structure makes it possible to suppress the Mullins-Sekerka instability and to reduce the occurrence of abnormal growth of polycrystals, pits, and the like. The quality of the group III nitride crystal can be thus improved.

### <Outline of Method for Producing Group III Nitride Crystal>

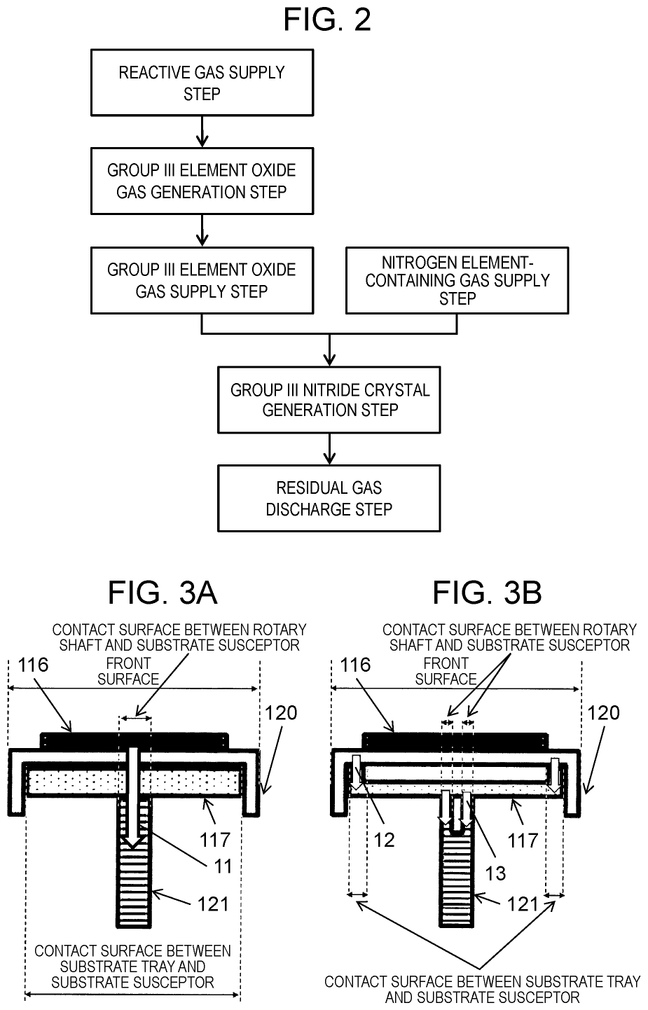

An outline of a method for producing a group III nitride crystal according to the first exemplary embodiment of the present disclosure will be described with reference to the flowchart of FIG. 2. The method for producing a group III nitride crystal according to the first exemplary embodiment includes a reactive gas supply step, a group III element oxide gas generation step, a group III element oxide gas supply step, a nitrogen element-containing gas supply step, a group III nitride crystal generation step, and a residual gas discharge step.

In the reactive gas supply step, a reactive gas is supplied from reactive gas supply pipe 103 to raw material reaction room 101 in raw material chamber 100. As described above, as the reactive gas, a reducing gas or an oxidizing gas may be used as necessary.

In the group III element oxide gas generation step, starting group III element source 105 is caused to react with the reactive gas (reducing gas when the starting group III element source is oxide, oxidizing gas when the starting group III element source is metal) in raw material reaction room 101 to generate a group III element oxide gas.

In the group III element oxide gas supply step, the group III element oxide gas produced in the group III element oxide gas generation step is supplied to growth chamber 111. The group III element oxide gas is discharged from the inside of raw material reaction room 101 through group III element oxide gas discharge port 107, discharged from gas discharge port 108 together with the first carrier gas supplied from first carrier gas supply port 102, carried through connection pipe 109, and supplied from gas supply port 118 into growth chamber 111.

In the nitrogen element-containing gas supply step, a nitrogen element-containing gas is supplied from nitrogen element-containing gas supply port 113 to growth chamber 111.

In the group III nitride crystal generation step, the group III element oxide gas supplied into growth chamber 111 in the group III element oxide gas supply step and the nitrogen element-containing gas supplied into growth chamber 111 in the nitrogen element-containing gas supply step are caused to react to grow a group III nitride crystal on seed substrate 116.

In the residual gas discharge step, unreacted gas that does not contribute to generation of the group III nitride crystal is discharged from discharge port 119 to the outside of growth chamber 111.

In the flowchart, the steps are indicated with arrows between the steps, but in practice, the steps illustrated in the flowchart may be performed simultaneously. The flowchart is illustrated with arrows from a step performed upstream to a step performed downstream in the device for producing a group III nitride crystal.

### <Details of Method and Device for Producing Group III Nitride Crystal>

Details of the method for producing a group III nitride crystal according to the first exemplary embodiment will be described. In the first exemplary embodiment, metal Ga is used as starting group III element source 105.

In the reactive gas supply step, a reactive gas is supplied from reactive gas supply pipe 103 to raw material reaction room 101. In the example of the first exemplary embodiment, since metal Ga is used as starting group III element source 105, H₂O gas is used as the reactive gas. As the reactive gas, O₂ gas, CO gas, NO gas, N₂O gas, NO₂ gas, or N₂O₄ gas may be used.

In the group III element oxide gas generation step, the reactive gas supplied to raw material reaction room 101 in the reactive gas supply step reacts with Ga as starting group III element source 105 to generate Ga₂O gas as a group III element oxide gas. The produced Ga₂O gas is discharged from raw material reaction room 101 to raw material chamber 100 via group III element oxide gas discharge port 107. The discharged Ga₂O gas is mixed with the first carrier gas supplied from first carrier gas supply port 102 to raw material chamber 100 and is supplied to gas discharge port 108.

In the first exemplary embodiment, first heater 106 heats raw material chamber 100. When raw material chamber 100 is heated, the temperature of raw material chamber 100 is preferably more than or equal to 800° C., which is higher than the boiling point of the Ga₂O gas. The temperature of raw material chamber 100 is preferably lower than the temperature of growth chamber 111. As described later, when second heater 115 heats growth chamber 111, the temperature of raw material chamber 100 is preferably less than 1800° C., for example. Starting group III element source 105 is placed in raw material boat 104 disposed in raw material reaction room 101. Raw material boat 104 preferably has a shape capable of increasing the contact area between the reactive gas and starting group III element source 105. Raw material boat 104 preferably has a multi-stage dish shape to prevent starting group III element source 105 and the reactive gas from passing through raw material reaction room 101 in a non-contact state, for example.

Methods for producing the group III element oxide gas are roughly classified into a method for reducing starting group III element source 105 and a method for oxidizing starting group III element source 105. For example, in the reduction method, an oxide (for example, Ga₂O₃) is used as starting group III element source 105, and a reducing gas (for example, H₂ gas, CO gas, CH₄ gas, C₂H₆ gas, H₂S gas, or SO₂ gas) is used as the reactive gas.

In the oxidation method, an oxide (for example, liquid Ga) is used as starting group III element source 105, and an oxidizing gas (for example, H₂O gas, O₂ gas, CO gas, NO gas, N₂O gas, NO₂ gas, or N₂O₄ gas) is used as the reactive gas. As starting group III element source 105, an In source or an Al source may be used in addition to the Ga source. As the first carrier gas, an inert gas, H₂ gas, or the like may be used.

In the group III element oxide gas supply step, the Ga₂O gas generated in the group III element oxide gas generation step is supplied to growth chamber 111 via gas discharge port 108, connection pipe 109, and gas supply port 118. When the temperature of connection pipe 109 connecting raw material chamber 100 and growth chamber 111 is lower than the temperature of raw material chamber 100, a reverse reaction of the reaction for generating the group III element oxide gas occurs, and starting group III element source 105 may precipitate in connection pipe 109. Thus, connection pipe 109 is preferably heated by third heater 110 to have a temperature not lower than the temperature of raw material chamber 100.

In the nitrogen element-containing gas supply step, the nitrogen element-containing gas is supplied from nitrogen element-containing gas supply port 113 to growth chamber 111. Examples of the nitrogen element-containing gas include NH₃ gas, NO gas, NO₂ gas, N₂O gas, N₂O₄ gas, N₂H₂ gas, and N₂H₄ gas.

In the group III nitride crystal generation step, the raw material gas supplied into growth chamber 111 through each supply step is caused to react to grow a group III nitride crystal on seed substrate 116. Second heater 115 preferably heats growth chamber 111 to a temperature at which the group III element oxide gas and the nitrogen element-containing gas react with each other. At this time, to prevent the occurrence of a reverse reaction of the reaction for generating the group III element oxide gas, it is preferable to control temperature of growth chamber 111 so that temperature of growth chamber 111 does not become lower than the temperature of raw material chamber 100 and the temperature of connection pipe 109. The temperature of growth chamber 111 heated by second heater 115 is preferably from 1000° C. to 1800° C., inclusive.

Mixing the group III element oxide gas supplied to growth chamber 111 through the group III element oxide supply step and the nitrogen element-containing gas supplied to growth chamber 111 through the nitrogen element-containing gas supply step upstream of seed substrate 116 allows a group III nitride crystal to grow on seed substrate 116.

### <Heat Release Promoting Structure>

Device 200 for producing a group III nitride crystal according to the first exemplary embodiment has a structure in which heat release from the back surface side of seed substrate 116 is promoted by substrate tray 120, substrate susceptor 117, and rotary shaft 121 used in the group III nitride crystal generation step, that is, a heat release promoting structure. Substrate tray 120 and substrate susceptor 117 have a structure in which they are in contact with each other as illustrated in FIGS. 3A and 3B. For example, when substrate tray 120 and substrate susceptor 117 are brought into contact with each other on the entire surface, the contact surface has a structure as illustrated in FIG. 3A.

On the other hand, a structure in which a space is formed between substrate tray 120 and substrate susceptor 117 is also possible. For example, as illustrated in FIG. 3B, this structure avoids contact with the central portion of substrate tray 120. For example, a disk shape is used as substrate tray 120 and substrate susceptor 117, and when contact is avoided, a shape having a circular recess is conceivable.

FIGS. 3A and 3B are schematic views, and the size, ratio, and the like of each component may be different from the actual size, ratio, and the like. Substrate tray 120 and substrate susceptor 117 may have an integrated structure.

Examples of the material of substrate tray 120 and substrate susceptor 117 include SiC, C (carbon), BN (boron nitride), a transition metal, SiO₂ (quartz), SiN (silicon nitride), and AlN (aluminum nitride).

As illustrated in FIGS. 3A and 3B, rotary shaft 121 and substrate susceptor 117 are at least partially in contact with each other. For example, when rotary shaft 121 and substrate susceptor 117 are brought into contact with each other on the entire surface, the contact surface has a structure as illustrated in FIG. 3A. FIG. 3A is a schematic sectional view illustrating an example of shapes of substrate tray 120, substrate susceptor 117, and rotary shaft 121 when substrate tray 120 and substrate susceptor 117 are in contact with each other on the entire surface, and substrate susceptor 117 and rotary shaft 121 are in contact with each other on the entire surface.

On the other hand, a structure in which a space is formed between rotary shaft 121 and substrate susceptor 117 is also possible. For example, as illustrated in FIG. 3B, this structure avoids contact with the central portion of rotary shaft 121. FIG. 3B is a schematic sectional view illustrating an example of shapes of substrate tray 120, substrate susceptor 117, and rotary shaft 121 in a case where substrate tray 120 and substrate susceptor 117 are partially in contact with each other, and substrate susceptor 117 and rotary shaft 121 are partially in contact with each other. In FIG. 3B, heat from the back surface of seed substrate 116 transfers from the peripheral edge of seed substrate 116 to the outside via the peripheral edge of substrate tray 120 and rotary shaft 121 as indicated by arrows 12 and 13. For example, a cylindrical shape is used as rotary shaft 121, and when contact with the entire surface of substrate susceptor 117 is avoided, for example, a shape having a circular recess is conceivable. FIGS. 3A and 3B are schematic views, and the size, ratio, and the like of each component may be different from the actual size, ratio, and the like.

Examples of the material of rotary shaft 121 include SiC, C (carbon), BN (boron nitride), a transition metal, SiO₂ (quartz), SiN (silicon nitride), and AlN (aluminum nitride). In addition, rotary shaft 121 preferably has a structure capable of circulating cooling water inside the rotary shaft to further promote heat release from the back surface side of seed substrate 116.

In the group III nitride crystal generation step, second heater 115 warms the front surface side of seed substrate 116. The flow of heat release of seed substrate 116 is considered as follows, for example.
i) First, the heat of seed substrate 116 transfers to substrate tray 120.
ii) Next, the heat transfers from substrate tray 120 to substrate susceptor 117.
iii) Finally, the heat transfers from substrate susceptor 117 to rotary shaft 121, whereby heat conduction occurs from the front surface side to the back surface side of seed substrate 116.

In the case of FIG. 3A, the heat from the back surface of seed substrate 116 transfers from the center of the back surface of seed substrate 116 to the outside via substrate tray 120 and rotary shaft 121 as indicated by arrow 11.

In the case of FIG. 3B, substrate tray 120 and substrate susceptor 117 are not in contact with each other on the entire surface, and heat transfers to substrate susceptor 117 not via the center of substrate tray 120 but via the peripheral edge as indicated by arrow 12. Substrate susceptor 117 and rotary shaft 121 are not in contact with each other on the entire surface, and heat transfers through the peripheral edge of the rotary shaft as indicated by arrow 13.

To control the heat conduction, it is desirable to have a configuration in which the contact area between substrate tray 120 and substrate susceptor 117 can be adjusted. For example, as in the structure illustrated in FIG. 3B, a recess may be provided at the center of substrate susceptor 117 so that the contact area with substrate tray 120 can be adjusted. As illustrated in FIGS. 1 and 3A, a structure may be taken in which rotary shaft 121 is in contact with the center of substrate susceptor 117 to avoid fourth heater 122. In this case, heat release from the back surface of seed substrate 116 is performed with the back surface of substrate tray 120 and the front surface of substrate susceptor 117 being in contact with each other on the entire surface. Thus, heat release from the center of substrate tray 120 and substrate susceptor 117 is promoted, that is, heat release from the center of seed substrate 116 is promoted.

On the other hand, as illustrated in FIG. 3B, when a space is formed between substrate tray 120 and substrate susceptor 117 by providing a recess at the center of substrate susceptor 117, heat release from a portion in contact with substrate susceptor 117 is promoted. For example, when a temperature distribution of the wafer surface occurs such as a temperature decrease from the outside to the center of seed substrate 116, the temperature distribution of the wafer surface can be adjusted by shifting the contact position between substrate tray 120 and substrate susceptor 117 or adjusting the contact area. Reducing the difference in temperature distribution on the wafer surface further improves the quality of the grown crystal in the plane.

Fourth heater 122 is provided to shorten the temperature rise time of seed substrate 116. In the step of raising the temperature of seed substrate 116 by heating, the temperature rise time becomes longer and the process time becomes longer only with second heater 115, and thus, the heating is assisted by fourth heater immediately below the substrate. After the heating to the desired temperature is completed, seed substrate 116 is heated mainly by the second heater.

Examples of seed substrate 116 include gallium nitride, gallium arsenide, silicon, sapphire, silicon carbide, zinc oxide, gallium oxide, and ScAlMgO₄.

As the second carrier gas, an inert gas, H₂ gas, or the like may be used.

Unreacted group III element oxide gas and nitrogen element-containing gas, and the first carrier gas, the second carrier gas, and the third carrier gas are discharged from discharge port 119.

### EXAMPLES

### Overview of Examples and Comparative Examples

A group III nitride crystal was grown using the growth furnace illustrated in FIG. 1. Here, GaN was grown as the group III nitride crystal. A liquid Ga was used as the starting Ga source, Ga was caused to react with H₂O gas as the reactive gas, and Ga₂O gas was used as the group III element oxide gas. NH₃ gas was used as the nitrogen element-containing gas, and a mixture of H₂ gas and N₂ gas was used as the first carrier gas and the second carrier gas. As the seed substrate, a GaN self-standing substrate was used. The generated polycrystals were estimated from optically observing the crystal surface, and the growth rate was estimated from the amount of change in weight.

### Comparative Example 1

The temperature of the raw material part was set to 1140° ° C., the temperature of the substrate surface was set to 1144° C., and the temperature gradient of the substrate inner layer was set to −0.3° C./cm. Crystal growth was performed for 6 hours with the partial pressure of Ga₂O gas set to 5.07×10⁻⁴ atm, the partial pressure of H₂O gas set to 5.66×10⁻⁴ atm, the partial pressure of NH₃ gas set to 4.82×10⁻¹ atm, the partial pressure of H₂ gas set to 1.33×10⁻² atm, and the partial pressure of N₂ gas set to 5.04×10⁻¹ atm in the growth chamber. A substrate tray having an area ratio of the contact surface between the substrate tray and the substrate susceptor to the surface area of the substrate tray (contact area/surface area) of 0.074 was used. The ratio of the contact area between the substrate tray and the substrate susceptor to the contact area between the rotary shaft and the substrate susceptor (contact area between substrate tray and substrate susceptor/contact area between rotary shaft and substrate susceptor) was 8.82. As a result of evaluating the grown crystal, the number of polycrystals on the surface of the grown crystal was 7.2 pieces/cm². The growth rate was 38 μm/h.

### Example 1

The temperature of the raw material part was set to 1140° ° C., the temperature of the substrate surface was set to 1127° C., and the temperature gradient of the substrate inner layer was set to 1.1° C./cm. Crystal growth was performed for 6 hours with the partial pressure of Ga₂O gas set to 4.98×10⁻⁴ atm, the partial pressure of H₂O gas set to 5.74×10⁻⁴ atm, the partial pressure of NH₃ gas set to 4.82×10⁻¹ atm, the partial pressure of H₂ gas set to 1.33×10⁻² atm, and the partial pressure of N₂ gas set to 5.04×10⁻¹ atm in the growth chamber. A substrate susceptor having an area ratio of the contact surface to the surface (contact area/surface area) of 0.453 was used. The ratio of the contact area between the substrate tray and the substrate susceptor to the contact area between the rotary shaft and the substrate susceptor (contact area between substrate tray and substrate susceptor/contact area between rotary shaft and substrate susceptor) was 53.81. As a result of evaluating the grown crystal, the number of polycrystals on the surface of the grown crystal was 4.1 pieces/cm². The growth rate was 78 μm/h.

### Example 2

The temperature of the raw material part was set to 1140° C., the temperature of the substrate surface was set to 1161° C., and the temperature gradient of the substrate inner layer was set to 1.5° C./cm. Crystal growth was performed for 6 hours with the partial pressure of Ga₂O gas set to 4.79×10⁻⁴ atm, the partial pressure of H₂O gas set to 5.94×10⁻⁴ atm, the partial pressure of NH₃ gas set to 4.82×10⁻¹ atm, the partial pressure of H₂ gas set to 1.33×10⁻² atm, and the partial pressure of N₂ gas set to 5.04×10⁻¹ atm in the growth chamber. A substrate tray having an area ratio of the contact surface between the substrate tray and the substrate susceptor to the surface area of the substrate tray (contact area/surface area) of 0.725 was used. The ratio of the contact area between the substrate tray and the substrate susceptor to the contact area between the rotary shaft and the substrate susceptor (contact area between substrate tray and substrate susceptor/contact area between rotary shaft and substrate susceptor) was 86.10. As a result of evaluating the grown crystal, the number of polycrystals on the surface of the grown crystal was 0.9 pieces/cm². The growth rate was 72 μm/h.

### Example 3

The temperature of the raw material part was set to 1140° C., the temperature of the substrate surface was set to 1174° C., and the temperature gradient of the substrate inner layer was set to 1.8° C./cm. Crystal growth was performed for 6 hours with the partial pressure of Ga₂O gas set to 5.40×10⁻⁴ atm, the partial pressure of H₂O gas set to 5.33×10⁻⁴ atm, the partial pressure of NH₃ gas set to 4.82×10⁻¹ atm, the partial pressure of H₂ gas set to 1.33×10⁻² atm, and the partial pressure of N₂ gas set to 5.04×10⁻¹ atm in the growth chamber. A substrate tray having an area ratio of the contact surface between the substrate tray and the substrate susceptor to the surface area of the substrate tray (contact area/surface area) of 0.815 was used. The ratio of the contact area between the substrate tray and the substrate susceptor to the contact area between the rotary shaft and the substrate susceptor (contact area between substrate tray and substrate susceptor/contact area between rotary shaft and substrate susceptor) was 96.86. As a result of evaluating the grown crystal, the number of polycrystals on the surface of the grown crystal was 0.6 pieces/cm². The growth rate was 51 μm/h.

### Example 4

The temperature of the raw material part was set to 1140° ° C., the temperature of the substrate surface was set to 1163º° C., and the temperature gradient of the substrate inner layer was set to 2.8° C./cm. Crystal growth was performed for 6 hours with the partial pressure of Ga₂O gas set to 5.07×10⁻⁴ atm, the partial pressure of H₂O gas set to 5.66×10⁻⁴ atm, the partial pressure of NH₃ gas set to 4.82×10⁻¹ atm, the partial pressure of H₂ gas set to 1.33×10⁻² atm, and the partial pressure of N₂ gas set to 5.04×10⁻¹ atm in the growth chamber. A substrate tray having an area ratio of the contact surface between the substrate tray and the substrate susceptor to the surface area of the substrate tray (contact area/surface area) of 0.900 was used. The ratio of the contact area between the substrate tray and the substrate susceptor to the contact area between the rotary shaft and the substrate susceptor (contact area between substrate tray and substrate susceptor/contact area between rotary shaft and substrate susceptor) was 118.82. As a result of evaluating the grown crystal, the number of polycrystals on the surface of the grown crystal was 0.4 pieces/cm². The growth rate was 51 μm/h.

### Summary of Examples and Comparative Examples

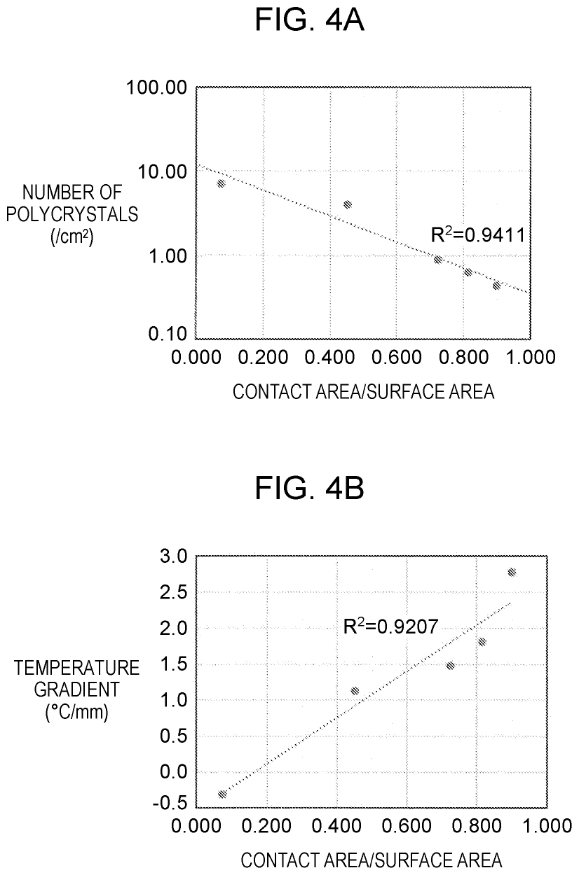

FIG. 4A illustrates the relationship between the ratio of the contact area to the surface area and the number of polycrystals generated in the grown crystal. The straight line indicated by a broken line is an approximate line created based on the experimental results. The coefficient of determination R² is more than 0.9, which indicates good approximation. As can be seen from this result, it is confirmed that the polycrystals tend to be reduced as the ratio between the contact area and the surface area (contact area/surface area) increases. This is because the temperature gradient [(front surface side)−(back surface side)] from the crystal front surface to the back surface is increased by increasing the ratio between the contact area and the surface area (contact area/surface area) as illustrated in FIG. 4B. That is, the increase in the temperature gradient suppressed the Mullins-Sekerka instability, which enabled stable single crystal growth, and the polycrystals were reduced. The straight line indicated by a broken line in FIG. 4B is also an approximate line created based on the experimental results, and the coefficient of determination R² exceeds 0.9, which indicates good approximation.

The grown GaN crystal is processed into a wafer, and then a device such as a transistor or a diode is formed. At this time, since the crystal structure of the region where polycrystals are formed is significantly disturbed, desired device characteristics cannot be obtained with the region present immediately below an electrode at the time of device formation. When the heat release promoting structure used in the present disclosure is used, it is possible to reduce polycrystals that affect the improvement of the yield at the time of device production. For example, as compared with the case where (contact area/surface area) is 0, when (contact area/surface area) is 0.34 or more, polycrystals can be reduced by more than or equal to 70%, and a good crystal is obtained. Further, when (contact area/surface area) is 0.45 or more, polycrystal can be reduced by more than or equal to 80%, and a better crystal is obtained. Further, when (contact area/surface area) is 0.65 or more, polycrystals can be reduced by more than or equal to 90%, and an extremely good crystal is obtained. These resulting numerical values are values calculated on the basis of approximate lines.

Here, for example, when a pn junction diode which is an electronic device is considered, the electrode size is preferably more than or equal to 50 μm in diameter in consideration of an applied current density. When the electrode size of 50 μm is considered, the number of electrodes having a diameter of 50 μm overlapping the polycrystal is 0.0000785 per 1 cm² when the polycrystal density is 4 pieces/cm². That is, the probability that the electrode part matches the polycrystalline region is 0.0079%, and the non-defective rate is a good value of more than or equal to 99.99%. As can be seen from FIG. 4A, when (contact area/surface area) is more than or equal to 0.34, the polycrystalline density is less than or equal to 4 pieces/cm², and the non-defective rate of the pn diode is an extremely high value of more than or equal to 99.99%.

### INDUSTRIAL APPLICABILITY

The device for producing a group III nitride crystal according to the present disclosure, including a structure of promoting heat release from the back surface side of the seed substrate, can suppress generation of polycrystals and can produce a high-quality group III nitride crystal.

### REFERENCE MARKS IN THE DRAWINGS

11 heat flow path
12 heat flow path
13 heat flow path
100 raw material chamber
101 raw material reaction room
102 first carrier gas supply port
103 reactive gas supply pipe
104 raw material boat
105 starting group III element source
106 first heater
107 group III element oxide gas discharge port
108 gas discharge port
109 connection pipe
110 third heater
111 growth chamber
112 third carrier gas supply port
113 nitrogen element-containing gas supply port
114 second carrier gas supply port
115 second heater
116 seed substrate
117 substrate susceptor
118 gas supply port
119 discharge port
120 substrate tray
12 rotary shaft
122 fourth heater
200 device for producing group III nitride crystal

1. A device for producing a group III nitride crystal, the device comprising:
a raw material chamber that generates a group III element oxide gas; and
a growth chamber that causes the group III element oxide gas supplied from the raw material chamber to react with a nitrogen element-containing gas to generate a group III nitride crystal on a seed substrate,
wherein the growth chamber includes, on a back surface side of the seed substrate, a structure of promoting heat release from the back surface side of the seed substrate, the structure including:
a substrate tray on which the seed substrate is placed,
a substrate susceptor on which the substrate tray is placed, and
a rotary shaft on which the substrate susceptor is placed.

2. The device for producing a group III nitride crystal according to claim 1, wherein the substrate tray and the substrate susceptor are in contact with each other over an entire surface of the substrate susceptor.

3. The device for producing a group III nitride crystal according to claim 1, wherein the substrate tray and the substrate susceptor include:
a contact part where the substrate tray and the substrate susceptor are in contact with each other at a part of a surface of the substrate susceptor; and
a non-contact part where the substrate tray and the substrate susceptor are not in contact with each other.

4. The device for producing a group III nitride crystal according to claim 3, wherein the non-contact part between the substrate tray and the substrate susceptor overlaps a region where the rotary shaft is disposed in a plan view as viewed from a direction of the rotary shaft.

5. The device for producing a group III nitride crystal according to claim 3, wherein the non-contact part is larger than the region where the rotary shaft is disposed.

6. The device for producing a group III nitride crystal according to claim 3, wherein a ratio between a surface area of the substrate tray and a contact area is more than or equal to 0.34, the contact area being an area where the substrate tray and the substrate susceptor are in contact with each other.

7. The device for producing a group III nitride crystal according to claim 1, wherein the rotary shaft includes a structure that circulates cooling water inside the rotary shaft.

8. The device for producing a group III nitride crystal according to claim 1, wherein the substrate tray is made of a material including at least one selected from the group consisting of SiC, C, BN, SiO₂, SiN, AlN, and a transition metal.

9. The device for producing a group III nitride crystal according to claim 1, wherein the substrate susceptor is made of a material including at least one selected from the group consisting of SiC, C, BN, SiO₂, SiN, AlN, and a transition metal.

10. A method for producing a group III nitride crystal, the method comprising:
reacting a group III element source with a reactive gas to generate a group III element oxide gas;
reacting the group III element oxide gas with a nitrogen element-containing gas to generate a group III nitride crystal on a seed substrate; and
providing, on the seed substrate, a temperature gradient in which a difference between a front surface temperature of the seed substrate and a back surface temperature of the seed substrate obtained by subtracting the back surface temperature from the front surface temperature is 0 or a positive numerical value.
